(19) United States
(12) Patent Application Publication
(10) Pub. No.: US 2025/0348042 A1
(43) Pub. Date: Nov. 13, 2025

(54) Wireless Stop for Electromechanical Devices

(71) Applicant: DeepMind Technologies Limited, London (GB)

(72) Inventors: Mustafa Emre Karagozler, London (GB); Ken Harry Julia Caluwaerts, Los Angelos, CA (US); Stefano Saliceti, London (GB); Alexander Montague Ruben, London (GB)

(21) Appl. No.: 19/192,633

(22) Filed: Apr. 29, 2025

Related U.S. Application Data
(60) Provisional application No. 63/644,470, filed on May 8, 2024.

(51) Int. Cl. G05B 9/02; H03K 3/017; H03K 19/20

(52) U.S. Cl. CPC G05B 9/02; H03K 3/017; H03K 19/20

(57) ABSTRACT

A system is configured to perform operations including receiving, from a wireless transmitter of a remote stop switch associated with an electromechanical device, a predetermined stop signal and a heartbeat signal. The operations also include generating a first fault signal based on reception of the predetermined stop signal, and generating a second fault signal based on interruption of reception of the heartbeat signal. The operations further include causing operation of at least part of the electromechanical device to be stopped based on at least one of the first fault signal or the second fault signal indicating that the remote stop switch has been triggered.

### CROSS-REFERENCE TO RELATED APPLICATIONS

This application claims priority to U.S. Provisional Pat. App. No. 63/644,470, filed May 8, 2024, and titled “Wireless Stop for Electromechanical Devices,” which is hereby incorporated by reference as if fully set forth in this description.

### BACKGROUND

As technology advances, various types of electromechanical devices are being created for performing a variety of functions that may assist users. Electromechanical devices such as robots may be used for applications involving material handling, transportation, entertainment, welding, assembly, and dispensing, among others. Over time, the manner in which these electromechanical systems operate is becoming more intelligent, efficient, and intuitive. As electromechanical systems become increasingly prevalent in numerous aspects of modern life, it is desirable for electromechanical systems to be safe and efficient. Therefore, a demand for safe and efficient electromechanical systems has helped open up a field of innovation in actuators, movement, sensing techniques, as well as component design and assembly.

### SUMMARY

A remote stop switch and a corresponding wireless stop system may be used to stop operation of an electromechanical device such as a robot, vehicle, appliance, and/or other equipment. The remote stop switch may be configured to generate two types of signals to provide redundancy in the ability of the remote stop switch to stop operation of the electromechanical device, thereby improving the safety of the electromechanical device. Specifically, when the remote stop switch is not activated, the remote stop switch may be configured to generate and wirelessly transmit to the wireless stop system a heartbeat signal, thereby indicating that the electromechanical device is permitted to continue operating normally. When the remote stop switch is activated, the remote stop switch may be configured to generate and wirelessly transmit to the wireless stop system a predetermined stop signal, thereby indicating that the electromechanical device is to stop operating at least some of its components. Reception of the predetermined stop signal may be configured to cause the wireless stop system to generate a first fault signal, and interruption of the heartbeat signal may be configured to cause the wireless stop system to generate a second fault signal. Assertion of at least one of the first fault signal or the second fault signal (including assertion of both signals) may be sufficient to cause the wireless stop system to stop operation of the electromechanical device.

In a first example embodiment, a system may be configured to perform operations. The operations may include receiving, from a wireless transmitter of a remote stop switch associated with an electromechanical device, a predetermined stop signal. The operations may also include generating a first fault signal based on reception of the predetermined stop signal. The operations may additionally include receiving, from the wireless transmitter of the remote stop switch, a heartbeat signal. The operations may further include generating a second fault signal based on interruption of reception of the heartbeat signal. The operations may yet further include causing operation of at least part of the electromechanical device to be stopped based on at least one of the first fault signal or the second fault signal indicating that the remote stop switch has been triggered.

In a second example embodiment, a method may include receiving, from a wireless transmitter of a remote stop switch associated with an electromechanical device, a predetermined stop signal. The method may also include generating a first fault signal based on reception of the predetermined stop signal. The method may additionally include receiving, from the wireless transmitter of the remote stop switch, a heartbeat signal. The method may further include generating a second fault signal based on interruption of reception of the heartbeat signal. The method may yet further include causing operation of at least part of the electromechanical device to be stopped based on at least one of the first fault signal or the second fault signal indicating that the remote stop switch has been triggered.

In a third example embodiment, an electromechanical device may be configured to perform operations. The operations may include receiving, from a wireless transmitter of a remote stop switch associated with the electromechanical device, a predetermined stop signal. The operations may also include generating a first fault signal based on reception of the predetermined stop signal. The operations may additionally include receiving, from the wireless transmitter of the remote stop switch, a heartbeat signal. The operations may further include generating a second fault signal based on interruption of reception of the heartbeat signal. The operations may yet further include causing operation of at least part of the electromechanical device to be stopped based on at least one of the first fault signal or the second fault signal indicating that the remote stop switch has been triggered.

In a fourth example embodiment, a remote stop switch may include a remote stop button that, when activated, is configured to trigger transmission of a predetermined stop signal and interrupt transmission of a heartbeat signal. The remote stop button may include a first terminal that is open when the remote stop button is not activated and closed when the remote stop button is activated. The remote stop button may also include a second terminal that is closed when the remote stop button is not activated and open when the remote stop button is activated. The remote stop switch may also include a wireless transmitter configured to (i) transmit the predetermined stop signal when the first terminal is closed and (ii) transmit the heartbeat signal when the second terminal is closed. The predetermined stop signal might not be transmitted when the first terminal is open, and the heartbeat signal might not be transmitted when the second terminal is open.

In a fifth example embodiment, a system may include a processor and a non-transitory computer-readable medium having stored thereon instructions that, when executed by the processor, cause the processor to perform operations in accordance with the first example embodiment, the second example embodiment, the third example embodiment, and/or the fourth example embodiment.

In a sixth example embodiment, a non-transitory computer-readable medium may have stored thereon instructions that, when executed by a computing device, cause the computing device to perform operations in accordance with the first example embodiment, the second example embodiment, the third example embodiment, and/or the fourth example embodiment.

In a seventh example embodiment, a system may include various means for carrying out each of the operations of the first example embodiment, the second example embodiment, the third example embodiment, and/or the fourth example embodiment.

These, as well as other embodiments, aspects, advantages, and alternatives, will become apparent to those of ordinary skill in the art by reading the following detailed description, with reference where appropriate to the accompanying drawings. Further, this summary and other descriptions and figures provided herein are intended to illustrate embodiments by way of example only and, as such, that numerous variations are possible. For instance, structural elements and process steps can be rearranged, combined, distributed, eliminated, or otherwise changed, while remaining within the scope of the embodiments as claimed.

### BRIEF DESCRIPTION OF THE DRAWINGS

FIG. 1 illustrates an electromechanical system, in accordance with examples described herein.

FIG. 2 illustrates a wireless stop system, in accordance with examples described herein.

FIG. 3 illustrates circuitry, in accordance with examples described herein.

FIG. 4 illustrates circuitry, in accordance with examples described herein.

FIG. 5 illustrates a remote stop switch, in accordance with examples described herein.

FIG. 6 illustrates a flow chart, in accordance with examples described herein.

### DETAILED DESCRIPTION

Example methods, devices, and systems are described herein. It should be understood that the words “example” and “exemplary” are used herein to mean “serving as an example, instance, or illustration.” Any embodiment or feature described herein as being an “example,” “exemplary,” and/or “illustrative” is not necessarily to be construed as preferred or advantageous over other embodiments or features unless stated as such. Thus, other embodiments can be utilized and other changes can be made without departing from the scope of the subject matter presented herein.

Accordingly, the example embodiments described herein are not meant to be limiting. It will be readily understood that the aspects of the present disclosure, as generally described herein, and illustrated in the figures, can be arranged, substituted, combined, separated, and designed in a wide variety of different configurations.

Further, unless context suggests otherwise, the features illustrated in each of the figures may be used in combination with one another. Thus, the figures should be generally viewed as component aspects of one or more overall embodiments, with the understanding that not all illustrated features are necessary for each embodiment.

Additionally, any enumeration of elements, blocks, or steps in this specification or the claims is for purposes of clarity. Thus, such enumeration should not be interpreted to require or imply that these elements, blocks, or steps adhere to a particular arrangement or are carried out in a particular order. Unless otherwise noted, figures are not drawn to scale.

### I. OVERVIEW

An electromechanical device may include a stop system configured to stop operation of the electromechanical device. For example, the electromechanical device make take the form of a robot or a vehicle, among other possibilities. The stop system may allow, for example, at least some operations of the electromechanical device to be stopped based on and/or in response to activation (e.g., depression, engagement, triggering, etc.) of a remote stop switch in order to prevent the electromechanical system from performing unintended actions, causing damage, and/or otherwise behaving in undesirable ways. For example, activation of a button of the remote stop switch may cause physical movements of the electromechanical device to be stopped, actuators of the electromechanical device to be relaxed, and/or data processing by the electromechanical device to be paused, among other possibilities.

The stop system may be configured to stop operation of the electromechanical device based on any one of two signals—the reception of a stop signal or the interruption of a heartbeat signal. Reception of the stop signal by the stop system from the remote stop switch may affirmatively indicate that operation of the electromechanical system is to be stopped. Reception of the heartbeat signal by the stop system from the remote stop switch may affirmatively indicate that operation of the electromechanical system is to continue, and thus interruption of the heartbeat signal may implicitly indicate that operation of the electromechanical system is to be stopped. Any one of these signals may be sufficient to stop operation of the electromechanical system, thus providing multiple different mechanisms for stopping the electromechanical device to thereby increase the safety and redundancy thereof.

In some cases, the stop system may be implemented using circuitry configured to process the stop signal and the heartbeat signal using hardware components. For example, the stop signal and the heartbeat signal might not be processed using software, thereby preventing software-based attacks and/or errors (e.g., bugs) from affecting operation of the stop system. The button of the remote stop switch may be wired such that activation (e.g., depression, engagement, triggering, etc.) of the button simultaneously (i) interrupts generation and/or transmission of the heartbeat signal (e.g., by opening a normally-closed switch) and (ii) causes generation and transmission of the stop signal (e.g., by closing a normally-open switch). Power circuitry configured to provide and/or cut power to components of the electromechanical device based on signals from the remote stop switch may be symmetric with power circuitry configured to provide and/or cut power to components of the electromechanical device based on an on-board stop signal generated by an on-board stop switch provided on the electromechanical device, thus preventing wiring errors from adversely affecting operation of the stop system.

### II. EXAMPLE ELECTROMECHANICAL SYSTEMS

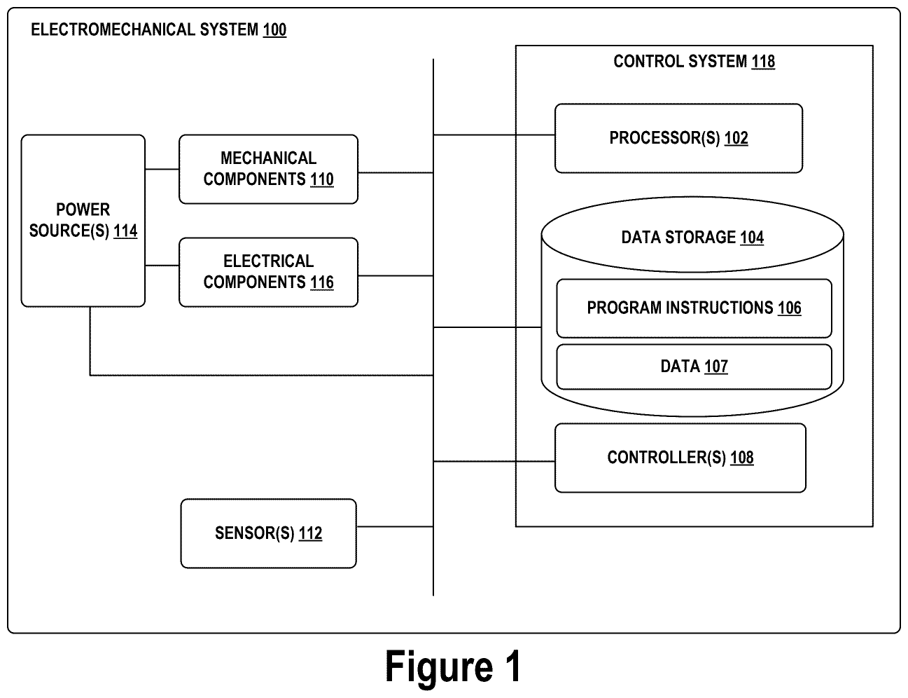

FIG. 1 illustrates an example configuration of electromechanical system 100 that may be used in connection with the implementations described herein. Electromechanical system 100 may be configured to operate autonomously, semi-autonomously, or using directions provided by user(s). Electromechanical system 100 may be implemented in various forms, such as a robot (e.g., robotic arm, industrial robot, mobile robot, humanoid robot, pet robot, home automation robot, quadruped, biped, etc.), a vehicle (e.g., ground vehicle, aerial vehicle, water vehicle, amphibious vehicle, etc.), and/or some other arrangement. Electromechanical system 100 may be engineered to be low cost at scale and designed to support a variety of tasks. Electromechanical system 100 may be designed to be capable of operating around people.

As shown in FIG. 1, electromechanical system 100 may include processor(s) 102, data storage 104, and controller(s) 108, which together may be part of control system 118. Electromechanical system 100 may also include sensor(s) 112, power source(s) 114, mechanical components 110, and electrical components 116. Nonetheless, electromechanical system 100 is shown for illustrative purposes, and may include more or fewer components. The various components of electromechanical system 100 may be connected in any manner, including wired or wireless connections. Further, in some examples, components of electromechanical system 100 may be distributed among multiple physical entities rather than a single physical entity. Other example illustrations of electromechanical system 100 may exist as well.

Processor(s) 102 may operate as one or more general-purpose hardware processors or special purpose hardware processors (e.g., digital signal processors, application specific integrated circuits, etc.). Processor(s) 102 may be configured to execute computer-readable program instructions 106, and manipulate data 107, both of which are stored in data storage 104. Processor(s) 102 may also directly or indirectly interact with other components of electromechanical system 100, such as sensor(s) 112, power source(s) 114, mechanical components 110, or electrical components 116.

Data storage 104 may be one or more types of hardware memory. For example, data storage 104 may include or take the form of one or more computer-readable storage media that can be read or accessed by processor(s) 102. The one or more computer-readable storage media can include volatile or non-volatile storage components, such as optical, magnetic, organic, or another type of memory or storage, which can be integrated in whole or in part with processor(s) 102. In some implementations, data storage 104 can be a single physical device. In other implementations, data storage 104 can be implemented using two or more physical devices, which may communicate with one another via wired or wireless communication. As noted previously, data storage 104 may include the computer-readable program instructions 106 and data 107. Data 107 may be any type of data, such as configuration data, sensor data, or diagnostic data, among other possibilities.

Controller 108 may include one or more electrical circuits, units of digital logic, computer chips, and/or microprocessors that are configured to (perhaps among other tasks) interface between any combination of mechanical components 110, sensor(s) 112, power source(s) 114, electrical components 116, control system 118, or a user of electromechanical system 100. In some implementations, controller 108 may be a purpose-built embedded device for performing specific operations with one or more subsystems of the electromechanical system 100.

Control system 118 may monitor and physically change the operating conditions of electromechanical system 100. In doing so, control system 118 may serve as a link between portions of electromechanical system 100, such as between mechanical components 110 or electrical components 116. In some instances, control system 118 may serve as an interface between electromechanical system 100 and another computing device. Further, control system 118 may serve as an interface between electromechanical system 100 and a user. In some instances, control system 118 may include various components for communicating with electromechanical system 100, including a joystick, buttons, and/or ports, etc. The example interfaces and communications noted above may be implemented via a wired or wireless connection, or both. Control system 118 may perform other operations for electromechanical system 100 as well.

During operation, control system 118 may communicate with other components and/or systems of electromechanical system 100 via wired or wireless connections, and may further be configured to communicate with one or more users of electromechanical system 100. As one possible illustration, control system 118 may receive an input (e.g., from a user or from another electromechanical device) indicating an instruction to perform a requested task, such as to pick up and move an object from one location to another location. Based on this input, control system 118 may perform operations to cause the electromechanical system 100 to make a sequence of movements to perform the requested task. As another illustration, a control system may receive an input indicating an instruction to move to a requested location. In response, control system 118 (perhaps with the assistance of other components or systems) may determine a direction and speed to move electromechanical system 100 through an environment en route to the requested location.

Operations of control system 118 may be carried out by processor(s) 102. Alternatively, these operations may be carried out by controller(s) 108, or a combination of processor(s) 102 and controller(s) 108. In some implementations, control system 118 may partially or wholly reside on a device other than electromechanical system 100, and therefore may at least in part control electromechanical system 100 remotely.

Mechanical components 110 represent hardware of electromechanical system 100 that may enable electromechanical system 100 to perform physical operations. As a few examples, electromechanical system 100 may include one or more physical members, such as an arm, an end effector, a head, a neck, a torso, a base, and wheels. The physical members or other parts of electromechanical system 100 may further include actuators arranged to move the physical members in relation to one another. Electromechanical system 100 may also include one or more structured bodies for housing control system 118 or other components, and may further include other types of mechanical components. The particular mechanical components 110 used in a given electromechanical system may vary based on the design of the electromechanical system, and may also be based on the operations or tasks the electromechanical system may be configured to perform.

In some examples, mechanical components 110 may include one or more removable components. Electromechanical system 100 may be configured to add or remove such removable components, which may involve assistance from a user or another electromechanical system. For example, electromechanical system 100 may be configured with removable end effectors or digits that can be replaced or changed as needed or desired. In some implementations, electromechanical system 100 may include one or more removable or replaceable battery units, control systems, power systems, bumpers, or sensors. Other types of removable components may be included within some implementations.

Electromechanical system 100 may include sensor(s) 112 arranged to sense aspects of electromechanical system 100. Sensor(s) 112 may include one or more force sensors, torque sensors, velocity sensors, acceleration sensors, position sensors, proximity sensors, motion sensors, location sensors, load sensors, temperature sensors, touch sensors, depth sensors, ultrasonic range sensors, infrared sensors, object sensors, or cameras, among other possibilities. Within some examples, electromechanical system 100 may be configured to receive sensor data from sensors that are physically separated from the electromechanical system (e.g., sensors that are positioned on other electromechanical systems or located within the environment in which the electromechanical system is operating).

Sensor(s) 112 may provide sensor data to processor(s) 102 (perhaps by way of data 107) to allow for interaction of electromechanical system 100 with its environment, as well as monitoring of the operation of electromechanical system 100. The sensor data may be used in evaluation of various factors for activation, movement, and deactivation of mechanical components 110 and electrical components 116 by control system 118. For example, sensor(s) 112 may capture data corresponding to the terrain of the environment or location of nearby objects, which may assist with environment recognition and navigation.

In some examples, sensor(s) 112 may include RADAR (e.g., for long-range object detection, distance determination, or speed determination), LIDAR (e.g., for short-range object detection, distance determination, or speed determination), SONAR (e.g., for underwater object detection, distance determination, or speed determination), VICON® (e.g., for motion capture), one or more cameras (e.g., stereoscopic cameras for 3D vision), a global positioning system (GPS) transceiver, or other sensors for capturing information of the environment in which electromechanical system 100 is operating. Sensor(s) 112 may monitor the environment in real time, and detect obstacles, elements of the terrain, weather conditions, temperature, or other aspects of the environment. In another example, sensor(s) 112 may capture data corresponding to one or more characteristics of a target or identified object, such as a size, shape, profile, structure, or orientation of the object.

Further, electromechanical system 100 may include sensor(s) 112 configured to receive information indicative of the state of electromechanical system 100, including sensor(s) 112 that may monitor the state of the various components of electromechanical system 100. Sensor(s) 112 may measure activity of systems of electromechanical system 100 and receive information based on the operation of the various features of electromechanical system 100, such as the operation of an extendable arm, an end effector, or other mechanical or electrical features of electromechanical system 100. The data provided by sensor(s) 112 may enable control system 118 to determine errors in operation as well as monitor overall operation of components of electromechanical system 100.

As an example, electromechanical system 100 may use force/torque sensors to measure load on various components of electromechanical system 100. In some implementations, electromechanical system 100 may include one or more force/torque sensors on mechanical components to measure the load on the actuators that move the mechanical components. In further examples, electromechanical system 100 may use one or more position sensors to sense the position of the actuators of the electromechanical system. For instance, such position sensors may sense states of extension, retraction, positioning, or rotation of the actuators on an arm or end effector.

As another example, sensor(s) 112 may include one or more velocity or acceleration sensors. For instance, sensor(s) 112 may include an inertial measurement unit (IMU). The IMU may sense velocity and acceleration in the world frame, with respect to the gravity vector. The velocity and acceleration sensed by the IMU may then be translated to that of electromechanical system 100 based on the location of the IMU in electromechanical system 100 and the kinematics of electromechanical system 100.

Electromechanical system 100 may include other types of sensors not explicitly discussed herein. Additionally or alternatively, the electromechanical system may use particular sensors for purposes not enumerated herein.

Electromechanical system 100 may also include one or more power source(s) 114 configured to supply power to various components of electromechanical system 100. Among other possible power systems, electromechanical system 100 may include a hydraulic system, electrical system, batteries, or other types of power systems. As an example illustration, electromechanical system 100 may include one or more batteries configured to provide charge to components of electromechanical system 100. Some of mechanical components 110 or electrical components 116 may each connect to a different power source, may be powered by the same power source, or be powered by multiple power sources.

Any type of power source may be used to power electromechanical system 100, such as electrical power or a gasoline engine. Additionally or alternatively, electromechanical system 100 may include a hydraulic system configured to provide power to mechanical components 110 using fluid power. Components of electromechanical system 100 may operate based on hydraulic fluid being transmitted throughout the hydraulic system to various hydraulic motors and hydraulic cylinders, for example. The hydraulic system may transfer hydraulic power by way of pressurized hydraulic fluid through tubes, flexible hoses, or other links between components of electromechanical system 100. Power source(s) 114 may charge using various types of charging, such as wired connections to an outside power source, wireless charging, combustion, or other examples.

Electrical components 116 may include various mechanisms capable of processing, transferring, or providing electrical charge or electric signals. Among possible examples, electrical components 116 may include electrical wires, circuitry, or wireless communication transmitters and receivers to enable operations of electromechanical system 100. Electrical components 116 may interwork with mechanical components 110 to enable electromechanical system 100 to perform various operations. Electrical components 116 may be configured to provide power from power source(s) 114 to the various mechanical components 110, for example. Further, electromechanical system 100 may include electric motors. Other examples of electrical components 116 may exist as well.

Electromechanical system 100 may include a body, which may connect to or house appendages and components of the electromechanical system. As such, the structure of the body may vary within examples and may further depend on particular operations that a given electromechanical system may have been designed to perform. For example, an electromechanical system developed to carry heavy loads may have a wide body that enables placement of the load. Similarly, an electromechanical system designed to operate in tight spaces may have a relatively tall, narrow body. Further, the body or the other components may be developed using various types of materials, such as metals or plastics. Within other examples, an electromechanical system may have a body with a different structure or made of various types of materials.

The body or the other components may include or carry sensor(s) 112. These sensors may be positioned in various locations on the electromechanical system 100, such as on a body, a head, a neck, a base, a torso, an arm, or an end effector, among other examples.

Electromechanical system 100 may be configured to carry a load, such as a type of cargo that is to be transported. In some examples, the load may be placed by the electromechanical system 100 into a bin or other container attached to the electromechanical system 100. The load may also represent external batteries or other types of power sources (e.g., solar panels) that the electromechanical system 100 may utilize. Carrying the load represents one example use for which the electromechanical system 100 may be configured, but the electromechanical system 100 may be configured to perform other operations as well.

As noted above, electromechanical system 100 may include various types of appendages, wheels, end effectors, gripping devices, rotors, and so on. In some examples, electromechanical system 100 may include a mobile base with wheels, treads, or some other form of locomotion. Additionally, electromechanical system 100 may include a robotic arm or some other form of robotic manipulator. In the case of a mobile base, the base may be considered as one of mechanical components 110 and may include wheels, powered by one or more of actuators, which allow for mobility of a robotic arm in addition to the rest of the body.

### III. EXAMPLE WIRELESS STOP SYSTEM

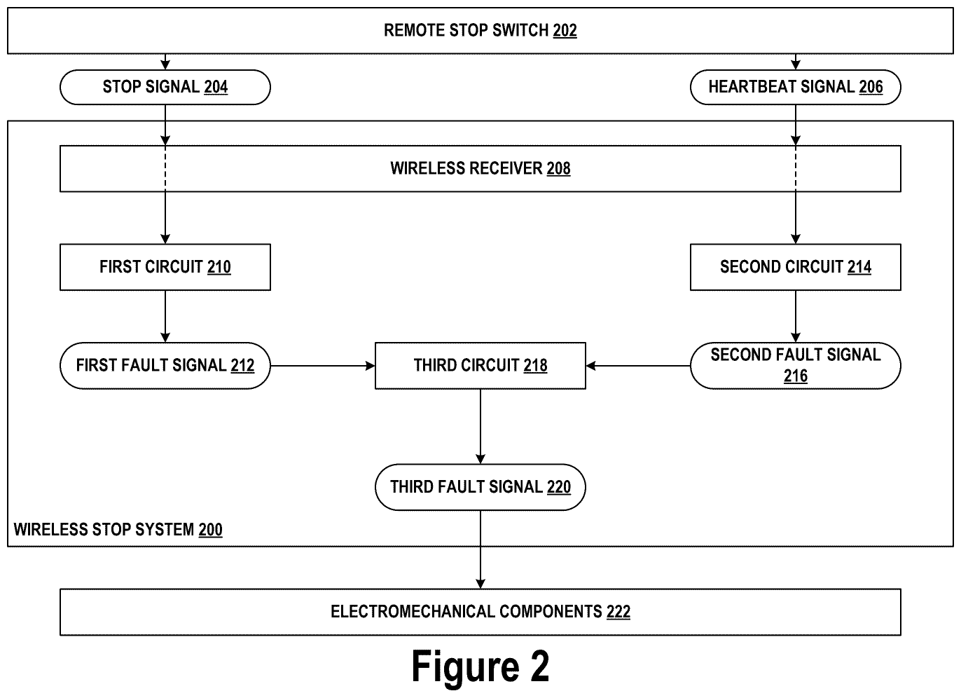

FIG. 2 illustrates an example wireless stop system 200. Wireless stop system may be implemented as part of and/or used in connection with electromechanical system 100. Wireless stop system 200 may include wireless receiver 208, first circuit 210, second circuit 214, and third circuit 218. Wireless stop system 200 may be used with remote stop switch 202. In some cases, remote stop switch 202 may be considered a logical (albeit physically separate) part of wireless stop system 200. When remote stop switch 202 is activated (e.g., depressed, engaged, triggered, etc.), wireless stop system 200 may be configured to generate third fault signal 220 and provide third fault signal 220 to electromechanical components 222. Based on and/or in response to reception of third fault signal 220, one or more of electromechanical components 222 may stop operating, moving, and/or performing corresponding functions. Electromechanical components 222 may include one or more electromechanical components of electromechanical system 100, such as power source(s) 114, mechanical components 110, and/or electrical components 116.

Remote stop switch 202 may be configured to generate and transmit, to wireless stop system 200, stop signal 204 and heartbeat signal 206. Stop signal 204 and heartbeat signal 206 may provide wireless stop system 200 with two different mechanisms for determining whether to stop operation of electromechanical components 222, thereby increasing the extent of safety provided by wireless stop system 200. In some implementations, both stop signal 204 and heartbeat signal 206 may be transmitted using a single channel between a transmitter of remote stop switch 202 and wireless receiver 208. In other implementations, stop signal 204 and heartbeat signal 206 may be transmitted using multiple different channels and/or multiple different instances of the transmitter and wireless receiver 208.

Generation and transmission of stop signal 204 by remote stop switch 202 may be configured to indicate that remote stop switch 202 has been activated (e.g., depressed, engaged, triggered, etc.). Thus, reception of stop signal 204 by wireless stop system 200 may indicate that electromechanical components 222 are to be stopped. Accordingly, the absence of stop signal 204 may indicate to wireless stop system 200 that electromechanical components 222 are to continue operating normally (e.g., electromechanical components 222 are not to be stopped). Stop signal 204 may include a predetermined waveform pattern.

Generation and transmission of heartbeat signal 206 by remote stop switch 202 may be configured to indicate that remote stop switch 202 has not been activated. Thus, reception of heartbeat signal 206 by wireless stop system 200 may indicate that electromechanical components 222 are to continue operating normally. Accordingly, interruption of reception of heartbeat signal 206 by wireless stop system 200 may indicate that electromechanical components 222 are to be stopped, for example, due to activation of remote stop switch 202, due to remote stop switch 202 moving out of range of wireless stop system 200, due to remote stop switch 202 being powered off, and/or due to remote stop switch 202 losing power (e.g., a battery thereof dying), among other possibilities. Heartbeat signal 206 may include a predetermined and/or periodic waveform pattern.

Wireless receiver 208 may be configured to receive stop signal 204 and/or heartbeat signal 206 from remote stop switch 202, and provide these signals and/or attributes thereof to first circuit 210 and second circuit 214. In some implementations, wireless receiver 208 may be configured to provide both stop signal 204 and heartbeat signal 206 to both first circuit 210 (which may be configured to detect stop signal 204 and ignore heartbeat signal 206) and second circuit 214 (which may be configured to detect heartbeat signal 206 and ignore stop signal 204). In other implementations, wireless receiver 208 may be configured to selectively provide (i) stop signal 204 to first circuit 210 (but not to second circuit 214) and (ii) heartbeat signal 206 to second circuit 214 (but not to first circuit 210).

In some cases, wireless receiver 208 may be associated with an address that disambiguates wireless receiver 208 from other wireless receivers of other wireless stop systems of other electromechanical systems. Thus, when the address of wireless receiver 208 is included in a transmission from remote stop switch 202, the transmission may be received and/or processed by wireless stop system 200 and ignored by other wireless stop systems. Thus, multiple instances of remote stop switch 202 and multiple instances of wireless stop system 200 may be operated in close proximity to one another without inadvertently triggering one another.

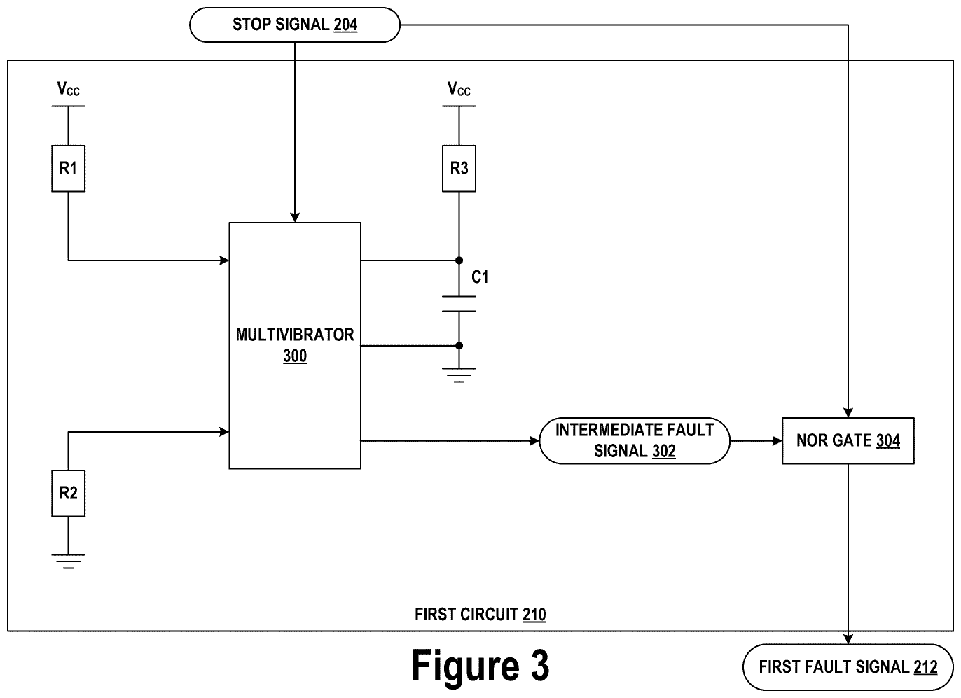

First circuit 210 may be configured to generate first fault signal 212 based on stop signal 204. Specifically, first circuit 210 may be configured to generate first fault signal 212 based on and/or in response to wireless receiver 208 receiving stop signal 204 and providing stop signal 204 (and/or attribute(s) thereof) to first circuit 210. Thus, first circuit 210 may be configured to, for example, detect a pattern associated with stop signal 204. An example implementation of first circuit 210 is illustrated in and discussed with respect to FIG. 3. Generating first fault signal 212 may involve first circuit 210 asserting an output thereof. Generating first fault signal 212 may take on the order of hundreds of milliseconds, and first fault signal 212 may thus alternatively be referred to as a fast stop signal.

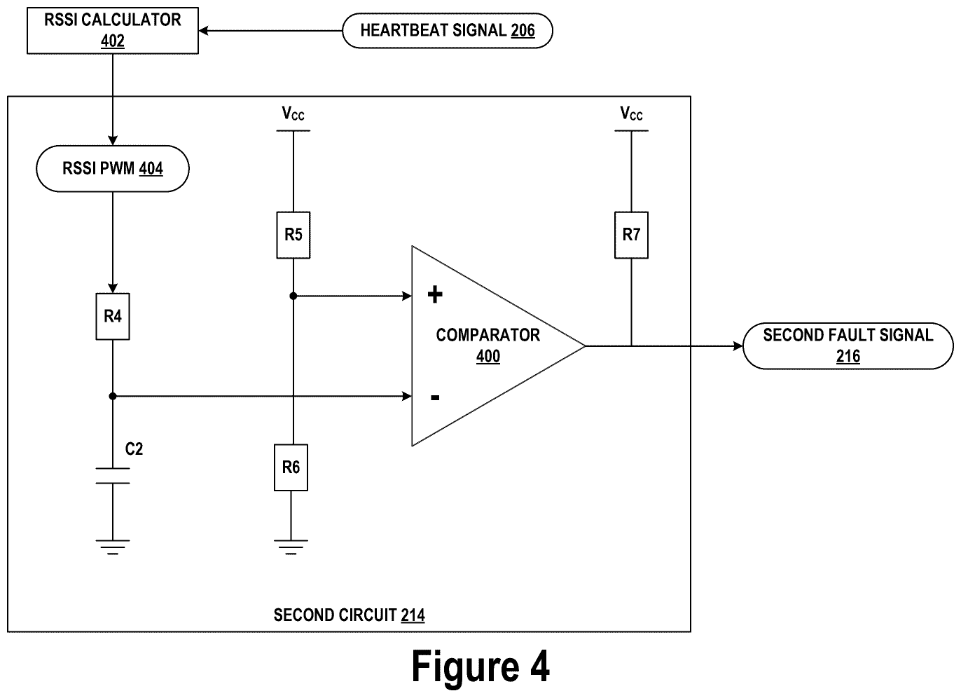

Second circuit 214 may be configured to generate second fault signal 216 based on interruption of heartbeat signal 206. Specifically, second circuit 214 may be configured to generate second fault signal 216 based on and/or in response to wireless receiver 208 not receiving heartbeat signal 206 and/or not providing heartbeat signal 206 (and/or attribute(s) thereof) to second circuit 214. Thus, second circuit 214 may be configured to abstain from generating (e.g., may deassert) second fault signal 216 while heartbeat signal 206 is detected by second circuit 214 (e.g., with sufficient signal strength). An example implementation of second circuit 214 is illustrated in and discussed with respect to FIG. 4. Generating second fault signal 216 may involve second circuit 214 asserting an output thereof. Generating second fault signal 216 may take on the order of seconds (e.g., 1-2 seconds), and second fault signal 216 may thus alternatively be referred to as a slow stop signal.

Third circuit 218 may be configured to generate third fault signal 220 when at least one of first fault signal 212 or second fault signal 216 is asserted. Third circuit 218 may include one or more logic gates configured to assert an output of third circuit 218 when at least one of first fault signal 212 or second fault signal 216 is asserted. For example, when each of first fault signal 212, second fault signal 216, and third fault signal 220 is active high, third circuit 218 may generate third fault signal 220 using an OR gate that receives first fault signal 212 and second fault signal 216 as inputs. Third fault signal 220, when asserted, may indicate that operation of electromechanical components 222 is to be stopped.

Accordingly, third circuit 218 may be configured to cause operation of at least part of electromechanical components 222 to be stopped when (i) heartbeat signal 206 is interrupted (e.g., lost due to low signal strength, lost due to activation of remote stop switch 202) and/or (ii) stop signal 204 is provided to wireless stop system 200. By providing two separate fault/stop mechanisms, each dependent on a different signal from remote stop switch 202, wireless stop system 200 may be more responsive (e.g., may stop operation of electromechanical components 222 more quickly) and safer (e.g., due to redundancies in the system) than alternative systems. Further, since continued operation of electromechanical components 222 depends on reception of heartbeat signal 206, electromechanical components 222 may operate as long as remote stop switch 202 remains operational and in-range of wireless stop system 200, thus ensuring that both fault/stop mechanisms are always available while electromechanical components 222 are operating.

In some implementations, third circuit 218 and/or electromechanical components 222 may include one or more logic gates, relays, and/or other components configured to cut power to one or more of electromechanical components 222 based on assertion of third fault signal 220. For example, wireless stop system 200 may include power circuitry configured to provide power to electromechanical components 222 when third fault signal 220 is not asserted and cut power to electromechanical components 222 when third fault signal 220 is asserted.

In some implementations, wireless stop system 200 may also include an on-board stop switch that, when activated (e.g., depressed, engaged, triggered, etc.), cuts power to electromechanical components 222. Circuitry and connectors associated with the on-board stop switch may be symmetric with circuitry and connectors associated with remote stop switch 202. For example, first power circuitry associated with the on-board stop button may be symmetric with second power circuitry associated with remote stop switch 202, and both power circuitries may be configured to cut power to electromechanical components 222 based on a fault signal originating from either remote stop switch 202 or the on-board stop switch. Thus, the first power circuitry and the second power circuitry may be configured to stop operation of electromechanical components 222 even if a connector of the on-board stop switch is accidentally connected to the second power circuitry and a connector associated with the remote stop switch 202 is accidentally connected to the first power circuitry.

In some implementations, third fault signal 220 may cause operation of some of electromechanical components 222 to be adjusted rather than stopped entirely. For example, third fault signal 220 may reduce an amount of force, torque, current, voltage, and/or power (among others) applied by and/or to some components of electromechanical system 220. For example, third fault signal 220 may reduce a force applied by one or more actuators of a robotic device, reduce a speed of a motor of a vehicle, and/or reduce a current applied to an appliance (e.g., household appliance, laboratory appliance, industrial appliance, etc.), among other possibilities.

### IV. EXAMPLE CIRCUITS

FIG. 3 illustrates an example implementation of first circuit 210. First circuit 210 may include multivibrator 300, NOR gate 304, resistor R1, resistor R2, resistor R3, and capacitor C1. As one example, multivibrator 300 may represent a TEXAS INSTRUMENTS™ 74HC123 monostable multivibrator, R1 may have a value of 10 kΩ and may be connected to pin 11 (2̅R̅) of multivibrator 300, R2 may have a value of 10 kΩ and may be connected to pin 9 (2̅A̅) of multivibrator 300, stop signal 204 may be connected to pin 10 (2B) of multivibrator 300, R3 may have a value of 39 kΩ, C1 may have a value of 1 μF, pin 6 (2C_{X}) of multivibrator 300 may be grounded, pin 7 (2R_{X}C_{X}) of multivibrator 300 may be connected between R3 and C1, and intermediate fault signal 302 (active low) may be generated by pin 12 (2̅Q̅) of multivibrator 300.

In one example, stop signal 204 may include a plurality of pulses that are spaced apart from one another by less than 10 milliseconds. For example, stop signal 204 may include a plurality of low pulses (e.g., alternating between a high level corresponding to V_{CC} and an active low level corresponding to GND) that are spaced apart from one another by less than 10 milliseconds. A rising edge of a first portion of stop signal 204 may cause multivibrator 300 to assert intermediate fault signal 302 for a first time period. The first time period may be based on, set by, and/or correspond to a time constant of the resistor-capacitor (RC) circuit formed by R3 and C1 (e.g., t_{W}=K*R3*C1, where t_{W} represents the first time period, K represents a predetermined constant of multivibrator 300 that varies with the operating voltage V_{CC}). The first time period may be long enough such that a low pulse of a second portion of stop signal 204 may overlap with (active low) assertion of intermediate fault signal 302, thereby causing NOR gate 304 to generate first fault signal 212. In the context of the example discussed above, t_{W}=14 milliseconds and K=0.48 when V_{CC}=3.3 Volts.

Using multivibrator 300 in combination with NOR gate 304 may prevent and/or reduce the likelihood of NOR gate 304 being triggered by spurious variations at the input of first circuit 210 which might otherwise be misinterpreted as stop signal 204. Further, in implementations where first circuit 210 receives as input both stop signal 204 and heartbeat signal 206, multivibrator 300 may prevent heartbeat signal 206 from causing assertion of first fault signal 212. Specifically, the values of R3 and C1 may be selected such that t_{W} is shorter than the period of heartbeat signal 206, thus preventing heartbeat signal 206 from triggering both multivibrator 300 and NOR gate 304.

FIG. 4 illustrates an example implementation of second circuit 214. Second circuit 214 may include comparator 400, resistor R4, resistor R5, resistor R6, resistor R7, and capacitor C2. As one example, comparator 400 may represent a TEXAS INSTRUMENTS™ LM393 differential comparator, R4 may have a value of 10 kΩ, R5 may have a value of 10 kΩ, R6 may have a value of 10 kΩ, R7 may have a value of 10 kΩ, and C2 may have a value of 10 μF, the positive input pin (+) of comparator 400 may be connected between R5 and R6, and the negative input pin (−) of comparator 400 may be connected between C2 and R4. Comparator 400 may be configured to assert second fault signal 216 when the voltage at the negative input pin thereof (i.e., voltage across C2) drops below the voltage at the positive input pin thereof (i.e., voltage across R6).

In one example, received signal strength indicator (RSSI) calculator 402 may be configured to generate RSSI pulse-width modulation (PWM) 404 based on heartbeat signal 206. RSSI calculator 402 may form part of wireless receiver 208 and/or second circuit 214, among other possibilities. RSSI PWM 404 may represent, using a duty cycle thereof, the RSSI associated with heartbeat signal 206. For example, when the RSSI ranges from 0 to 255, an RSSI of 0 may correspond to a 0% duty cycle, an RSSI of 127 may correspond to a 50% duty cycle, and an RSSI of 255 may correspond to a 100% duty cycle. Thus, RSSI calculator 402 may linearly map RSSI values associated with heartbeat signal 206 to the duty cycle of RSSI PWM 404. In other implementations, RSSI calculator 402 may be configured to measure a received signal strength of heartbeat signal 206 using other metrics (e.g., -dBm).

Values of R4, R5, R6, and C2 may be selected such that comparator 400 asserts second fault signal 216 when a received signal strength of heartbeat signal 206 drops below a threshold signal strength. Specifically, a voltage divider formed by R5 and R6 may define a reference voltage corresponding to the threshold signal strength, while an RC circuit formed by R4 and C2 may represent, using the voltage across C2, the received signal strength of heartbeat signal 206. The values of R5 and/or R6 may be modified to account for different extents of signal attenuation due to different materials in and/or usage contexts of remote stop switch 202 and/or wireless stop system 200. The RC circuit formed by C2 and R4 may operate as an integrator, thus allowing for some spurious variations in the received signal strength of heartbeat signal 206 before heartbeat signal 206 is considered to have been interrupted. Thus, second fault signal 216 may be asserted when the received signal strength of heartbeat signal 206 drops below the threshold signal strength for at least a predetermined period of time.

In some implementations, the operations performed by first circuit 210, second circuit 214, third circuit 218, and/or other aspects of wireless stop system 200 may be implemented using a processor configured to execute instructions that implement these operations. In further implementations, the operations may be performed using a combination of hardware circuitry and software instructions. Implementing the operations using circuitry, as illustrated in FIGS. 3 and 4, may make wireless stop system 200 easier to maintain and less prone to software-based errors, thus improving the safety and reliability of wireless stop system 200. For example, wireless stop system 200 might not be affected by software errors introduced by modifications of the software of wireless stop system 200 and/or modifications of software of other systems with which wireless stop system 200 interacts.

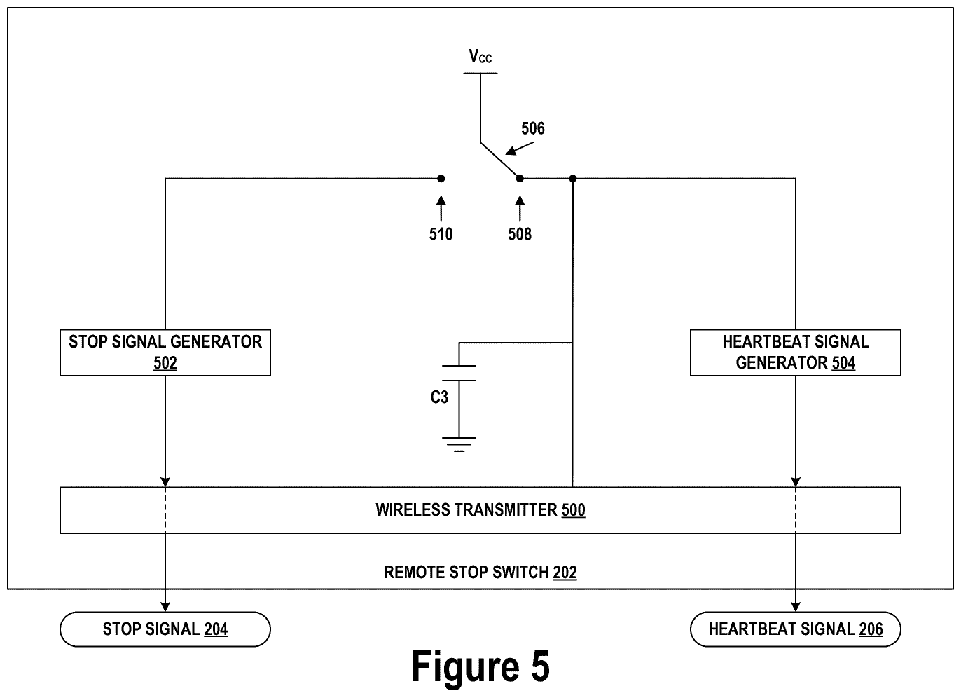

FIG. 5 illustrates an example implementation of remote stop switch 202. Remote stop switch 202 may include wireless transmitter 500, stop signal generator 502, heartbeat signal generator 504, power rail capacitor C3, switch 506, terminal 508 and terminal 510. Stop signal generator 502 may include circuitry and/or instructions configured to generate stop signal 204. Heartbeat signal generator 504 may include circuitry and/or instructions configured to generate heartbeat signal 206. Wireless transmitter 500 may include circuitry and/or instructions configured to transmit stop signal 204 and heartbeat signal 206 to wireless receiver 208 of wireless stop system 200. Wireless transmitter 500 may be paired with wireless receiver 208, and may thus include an address of wireless receiver 208 in association with data transmitted by wireless transmitter 500 to indicate the intended recipient of these transmissions, thereby reducing and/or preventing interference among multiple remote stop switches and/or wireless stop systems when operating nearby one another.

When a remote stop button of remote stop switch is not activated, switch 506 may connect a power rail (denoted as V_{cc}) of remote stop switch 202 to heartbeat signal generator 504 and wireless transmitter 500 by way of terminal 508 (normally closed), thereby allowing heartbeat signal 206 to be generated and transmitted by remote stop switch 202. When the remote stop button of remote stop switch is activated, switch 506 may disconnect the power rail from heartbeat signal generator 504 and wireless transmitter 500, and connect the power rail to stop signal generator 502 by way of terminal 510 (normally open). Thus, activation of the stop button may interrupt generation and transmission of heartbeat signal 206, and may allow stop signal 204 to be generated and transmitted by remote stop switch 202.

After switch 506 disconnects from terminal 508, C3 may allow wireless transmitter 500 to continue operating for at least long enough to transmit stop signal 204. Specifically, C3 may be sufficiently large (e.g., may include a plurality of capacitors) to operate as a temporary power source for wireless transmitter 500 to transmit at least one instance and/or sequence of stop signal 204. Disconnecting wireless transmitter 500 from the power rail, and relying instead on C3 to power wireless transmitter 500, provides a second layer of redundancy that prevents and/or reduces the likelihood of heartbeat signal 206 continuing to be transmitted after activation of the remote stop button. Thus, activation of the remote stop button is configured to (i) cut power to heartbeat signal generator 504, (ii) provide power to stop signal generator 502, and (iii) cut power to wireless transmitter 500, thereby providing three separate ways of indicating that operation of electromechanical components 222 is to be stopped.

### V. ADDITIONAL EXAMPLE OPERATIONS

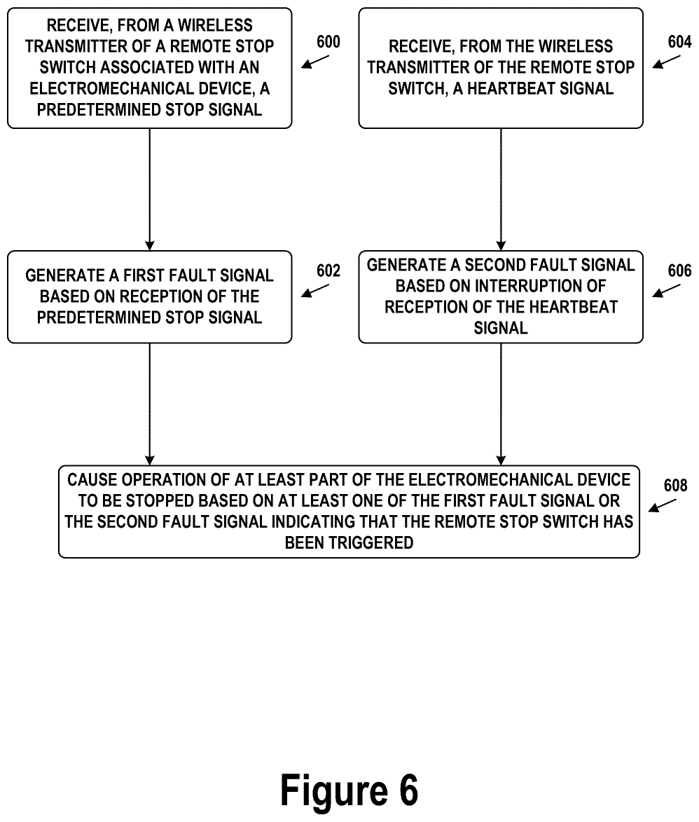

FIG. 6 illustrates a flow chart of operations related to stopping operation of an electromechanical device. The operations may be carried out by electromechanical system 100, wireless stop system 200, and/or remote stop switch 202, among other possibilities. The embodiments of FIG. 6 may be simplified by the removal of any one or more of the features shown therein. Further, these embodiments may be combined with features, aspects, and/or implementations of any of the previous figures or otherwise described herein.

Block 600 may involve receiving, from a wireless transmitter of a remote stop switch associated with an electromechanical device, a predetermined stop signal.

Block 602 may involve generating a first fault signal based on reception of the predetermined stop signal.

Block 604 may involve receiving, from the wireless transmitter of the remote stop switch, a heartbeat signal.

Block 606 may involve generating a second fault signal based on interruption of reception of the heartbeat signal.

Block 608 may involve causing operation of at least part of the electromechanical device to be stopped based on at least one of the first fault signal or the second fault signal indicating that the remote stop switch has been triggered.

In some examples, a first circuit may be configured to generate the first fault signal. The first circuit may include a multivibrator configured to generate, based on a first portion of the predetermined stop signal, an intermediate fault signal for at least a first time period. The first circuit may also include a first logic gate configured to generate the first fault signal based on detection of a second portion of the predetermined stop signal and the intermediate fault signal during the first time period. The second portion of the predetermined stop signal may follow the first portion of the predetermined stop signal.

In some examples, the multivibrator may include a monostable multivibrator.

In some examples, the first circuit may include a first resistor-capacitor (RC) circuit connected to the multivibrator and associated with a time constant corresponding to the first time period.

In some examples, generating the second fault signal may include determining that a signal strength of the heartbeat signal has dropped below a threshold signal strength.

In some examples, the signal strength may include and/or be represented by a received signal strength indicator (RSSI).

In some examples, a second circuit may be configured to generate the second fault signal. The second circuit may be configured to generate, based on the heartbeat signal, a pulse-width modulation (PWM) signal configured to represent, using a duty cycle thereof, a signal strength of the heartbeat signal. The second circuit may include a second resistor-capacitor (RC) circuit configured to receive the PWM signal and represent the duty cycle of the PWM signal using a voltage of a capacitor of the second RC circuit. The second circuit may also include a voltage divider configured to provide a reference voltage corresponding to the threshold signal strength. The second circuit may further include a comparator configured to generate the second fault signal based on the voltage of the capacitor dropping below the reference voltage.

In some examples, a third circuit may be configured to cause operation of the at least part of the electromechanical device to be stopped. The third circuit may include a second logic gate configured to generate a third fault signal when at least one of the first fault signal or the second fault signal indicates that the remote stop switch has been triggered. The third circuit may also include a third logic gate configured to cut power to one or more components of the electromechanical device based on the third fault signal indicating that the remote stop switch has been triggered.

In some examples, the remote stop switch may include a remote stop button that, when activated, is configured to trigger transmission of the predetermined stop signal and interrupt transmission of the heartbeat signal. The remote stop button may include a first terminal that is open when the remote stop button is not activated and closed when the remote stop button is activated and a second terminal that is closed when the remote stop button is not activated and open when the remote stop button is activated. The remote stop switch may also include the wireless transmitter, which may be configured to (i) transmit the predetermined stop signal when the first terminal is closed and (ii) transmit the heartbeat signal when the second terminal is closed. The predetermined stop signal might not be transmitted when the first terminal is open, and the heartbeat signal might not be transmitted when the second terminal is open.

In some examples, the remote stop switch may include a power rail. The wireless transmitter may be connected to the power rail by way of the second terminal when the second terminal is closed and disconnected from the power rail when the second terminal is open. The remote stop switch may also include a power rail capacitor connected to the power rail and the wireless transmitter. The power rail capacitor may be configured to power the wireless transmitter for at least a threshold time period after the second terminal is opened such that the predetermined stop signal is transmitted by the wireless transmitter prior to the wireless transmitter turning off.

In some examples, an on-board stop switch may be physically connected to the electromechanical device. The on-board stop switch may include an on-board stop button that (i), when not activated, may be configured to provide power to at least one component of the electromechanical device and (ii), when activated, may be configured to cut power to the at least one component of the electromechanical device. First power circuitry associated with the on-board stop switch may be symmetric with second power circuitry associated with the remote stop switch such that each of the on-board stop switch and the remote stop switch is configurable to control either one of the first power circuitry or the second power circuitry to cut power to the at least one component of the electromechanical device.

In some examples, the wireless transmitter of the remote stop switch may be paired with the electromechanical device and configured to include, in transmissions from the wireless transmitter to a receiver of the electromechanical device, an address that is associated with the receiver of the electromechanical device and configured to prevent the transmissions from stopping operation of other electromechanical devices.

In some examples, a first delay between transmission of the predetermined stop signal and generation of the first fault signal may be smaller than a second delay between interruption of reception of the heartbeat signal and generation of the second fault signal.

In some examples, the electromechanical device may include a robotic device.

In some examples, the robotic device may include a bipedal robot.

In some examples, the robotic device may include a quadrupedal robot.

In some examples, the electromechanical device may include a vehicle.

### VI. CONCLUSION

The present disclosure is not to be limited in terms of the particular embodiments described in this application, which are intended as illustrations of various aspects. Many modifications and variations can be made without departing from its scope, as will be apparent to those skilled in the art. Functionally equivalent methods and apparatuses within the scope of the disclosure, in addition to those described herein, will be apparent to those skilled in the art from the foregoing descriptions. Such modifications and variations are intended to fall within the scope of the appended claims.

The above detailed description describes various features and operations of the disclosed systems, devices, and methods with reference to the accompanying figures. In the figures, similar symbols typically identify similar components, unless context dictates otherwise. The example embodiments described herein and in the figures are not meant to be limiting. Other embodiments can be utilized, and other changes can be made, without departing from the scope of the subject matter presented herein. It will be readily understood that the aspects of the present disclosure, as generally described herein, and illustrated in the figures, can be arranged, substituted, combined, separated, and designed in a wide variety of different configurations.

With respect to any or all of the message flow diagrams, scenarios, and flow charts in the figures and as discussed herein, each step, block, and/or communication can represent a processing of information and/or a transmission of information in accordance with example embodiments. Alternative embodiments are included within the scope of these example embodiments. In these alternative embodiments, for example, operations described as steps, blocks, transmissions, communications, requests, responses, and/or messages can be executed out of order from that shown or discussed, including substantially concurrently or in reverse order, depending on the functionality involved. Further, more or fewer blocks and/or operations can be used with any of the message flow diagrams, scenarios, and flow charts discussed herein, and these message flow diagrams, scenarios, and flow charts can be combined with one another, in part or in whole.

A step or block that represents a processing of information may correspond to circuitry that can be configured to perform the specific logical functions of a herein-described method or technique. Alternatively or additionally, a block that represents a processing of information may correspond to a module, a segment, or a portion of program code (including related data). The program code may include one or more instructions executable by a processor for implementing specific logical operations or actions in the method or technique. The program code and/or related data may be stored on any type of computer readable medium such as a storage device including random access memory (RAM), a disk drive, a solid state drive, or another storage medium.

The computer readable medium may also include non-transitory computer readable media such as computer readable media that store data for short periods of time like register memory, processor cache, and RAM. The computer readable media may also include non-transitory computer readable media that store program code and/or data for longer periods of time. Thus, the computer readable media may include secondary or persistent long term storage, like read only memory (ROM), optical or magnetic disks, solid state drives, compact-disc read only memory (CD-ROM), for example. The computer readable media may also be any other volatile or non-volatile storage systems. A computer readable medium may be considered a computer readable storage medium, for example, or a tangible storage device.

Moreover, a step or block that represents one or more information transmissions may correspond to information transmissions between software and/or hardware modules in the same physical device. However, other information transmissions may be between software modules and/or hardware modules in different physical devices.

The particular arrangements shown in the figures should not be viewed as limiting. It should be understood that other embodiments can include more or less of each element shown in a given figure. Further, some of the illustrated elements can be combined or omitted. Yet further, an example embodiment can include elements that are not illustrated in the figures.

While various aspects and embodiments have been disclosed herein, other aspects and embodiments will be apparent to those skilled in the art. The various aspects and embodiments disclosed herein are for purpose of illustration and are not intended to be limiting, with the true scope being indicated by the following claims.

What is claimed is:

1. A system configured to perform operations comprising:
receiving, from a wireless transmitter of a remote stop switch associated with an electromechanical device, a predetermined stop signal;
generating a first fault signal based on reception of the predetermined stop signal;
receiving, from the wireless transmitter of the remote stop switch, a heartbeat signal;
generating a second fault signal based on interruption of reception of the heartbeat signal; and
causing operation of at least part of the electromechanical device to be stopped based on at least one of the first fault signal or the second fault signal indicating that the remote stop switch has been triggered.

2. The system of claim 1, further comprising a first circuit configured to generate the first fault signal, wherein the first circuit comprises:
a multivibrator configured to generate, based on a first portion of the predetermined stop signal, an intermediate fault signal for at least a first time period; and
a first logic gate configured to generate the first fault signal based on detection of (i) a second portion of the predetermined stop signal and (ii) the intermediate fault signal during the first time period, wherein the second portion of the predetermined stop signal follows the first portion of the predetermined stop signal.

3. The system of claim 2, wherein the multivibrator comprises a monostable multivibrator.

4. The system of claim 2, wherein the first circuit comprises a first resistor-capacitor (RC) circuit connected to the multivibrator and associated with a time constant corresponding to the first time period.

5. The system of claim 1, wherein generating the second fault signal comprises determining that a signal strength of the heartbeat signal has dropped below a threshold signal strength.

6. The system of claim 5, wherein the signal strength comprises a received signal strength indicator (RSSI).

7. The system of claim 5, further comprising a second circuit configured to generate the second fault signal, wherein the second circuit is configured to generate, based on the heartbeat signal, a pulse-width modulation (PWM) signal configured to represent, using a duty cycle thereof, a signal strength of the heartbeat signal, and wherein the second circuit comprises:
a second resistor-capacitor (RC) circuit configured to receive the PWM signal and represent the duty cycle of the PWM signal using a voltage of a capacitor of the second RC circuit;
a voltage divider configured to provide a reference voltage corresponding to the threshold signal strength; and
a comparator configured to generate the second fault signal based on the voltage of the capacitor dropping below the reference voltage.

8. The system of claim 1, further comprising a third circuit configured to cause operation of the at least part of the electromechanical device to be stopped, wherein the third circuit comprises:
a second logic gate configured to generate a third fault signal when at least one of the first fault signal or the second fault signal indicates that the remote stop switch has been triggered; and
a third logic gate configured to cut power to one or more components of the electromechanical device based on the third fault signal indicating that the remote stop switch has been triggered.

9. The system of claim 1, further comprising the remote stop switch, wherein the remote stop switch comprises:
a remote stop button that, when activated, is configured to trigger transmission of the predetermined stop signal and interrupt transmission of the heartbeat signal, wherein the remote stop button comprises:
a first terminal that is open when the remote stop button is not activated and closed when the remote stop button is activated; and
a second terminal that is closed when the remote stop button is not activated and open when the remote stop button is activated; and
the wireless transmitter configured to (i) transmit the predetermined stop signal when the first terminal is closed and (ii) transmit the heartbeat signal when the second terminal is closed, wherein the predetermined stop signal is not transmitted when the first terminal is open, and wherein the heartbeat signal is not transmitted when the second terminal is open.

10. The system of claim 9, wherein the remote stop switch comprises:
a power rail, wherein the wireless transmitter is connected to the power rail by way of the second terminal when the second terminal is closed and disconnected from the power rail when the second terminal is open; and
a power rail capacitor connected to the power rail and the wireless transmitter and configured to power the wireless transmitter for at least a threshold time period after the second terminal is opened such that the predetermined stop signal is transmitted by the wireless transmitter prior to the wireless transmitter turning off.

11. The system of claim 1, further comprising:
an on-board stop switch that is physically connected to the electromechanical device, wherein the on-board stop switch comprises an on-board stop button that (i), when not activated, is configured to provide power to at least one component of the electromechanical device and (ii), when activated, is configured to cut power to the at least one component of the electromechanical device, wherein first power circuitry associated with the on-board stop switch is symmetric with second power circuitry associated with the remote stop switch such that each of the on-board stop switch and the remote stop switch is configurable to control either one of the first power circuitry or the second power circuitry to cut power to the at least one component of the electromechanical device.

12. The system of claim 1, wherein the wireless transmitter of the remote stop switch is paired with the electromechanical device and configured to include, in transmissions from the wireless transmitter to a receiver of the electromechanical device, an address that is associated with the receiver of the electromechanical device and configured to prevent the transmissions from stopping operation of other electromechanical devices.

13. The system of claim 1, wherein a first delay between transmission of the predetermined stop signal and generation of the first fault signal is smaller than a second delay between interruption of reception of the heartbeat signal and generation of the second fault signal.

14. The system of claim 1, wherein the electromechanical device comprises one or more of a robotic device or a vehicle.

15. A method comprising:
receiving, from a wireless transmitter of a remote stop switch associated with an electromechanical device, a predetermined stop signal;
generating a first fault signal based on reception of the predetermined stop signal;
receiving, from the wireless transmitter of the remote stop switch, a heartbeat signal;
generating a second fault signal based on interruption of reception of the heartbeat signal; and
causing operation of at least part of the electromechanical device to be stopped based on at least one of the first fault signal or the second fault signal indicating that the remote stop switch has been triggered.

16. The method of claim 15, wherein generating the first fault signal comprises:
generating, using a multivibrator and based on a first portion of the predetermined stop signal, an intermediate fault signal for at least a first time period; and
generating the first fault signal using a first logic gate based on detection of (i) a second portion of the predetermined stop signal and (ii) the intermediate fault signal during the first time period, wherein the second portion of the predetermined stop signal follows the first portion of the predetermined stop signal.

17. The method of claim 15, wherein generating the second fault signal comprises determining that a signal strength of the heartbeat signal has dropped below a threshold signal strength.

18. The method of claim 15, wherein causing operation of the at least part of the electromechanical device to be stopped comprises:
generating a third fault signal when at least one of the first fault signal or the second fault signal indicates that the remote stop switch has been triggered; and
cutting power to one or more components of the electromechanical device based on the third fault signal indicating that the remote stop switch has been triggered.

19. A remote stop switch comprising:
a remote stop button that, when activated, is configured to trigger transmission of a predetermined stop signal and interrupt transmission of a heartbeat signal, wherein the remote stop button comprises:
a first terminal that is open when the remote stop button is not activated and closed when the remote stop button is activated; and
a second terminal that is closed when the remote stop button is not activated and open when the remote stop button is activated; and
a wireless transmitter configured to (i) transmit the predetermined stop signal when the first terminal is closed and (ii) transmit the heartbeat signal when the second terminal is closed, wherein the predetermined stop signal is not transmitted when the first terminal is open, and wherein the heartbeat signal is not transmitted when the second terminal is open.

20. The remote stop switch of claim 19, further comprising:
a power rail, wherein the wireless transmitter is connected to the power rail by way of the second terminal when the second terminal is closed and disconnected from the power rail when the second terminal is open; and
a power rail capacitor connected to the power rail and the wireless transmitter and configured to power the wireless transmitter for at least a threshold time period after the second terminal is opened such that the predetermined stop signal is transmitted by the wireless transmitter prior to the wireless transmitter turning off.
